(19) United States
(12) Patent Application Publication
(10) Pub. No.: US 2017/0338232 A1
(43) Pub. Date: Nov. 23, 2017

(54) METHOD OF FABRICATING SEMICONDUCTOR DEVICE

(71) Applicant: Samsung Electronics Co., Ltd., Suwon-si (KR)

(72) Inventors: Sang Chul HAN, Suwon-si (KR); Do Hyung KIM, Hwaseong-si (KR); Tae ki HONG, Suwon-si (KR); Jin Hyuk CHOI, Suwon-si (KR); Moon Hyeong HAN, Suwon-si (KR)

(21) Appl. No.: 15/432,697

(22) Filed: Feb. 14, 2017

(30) Foreign Application Priority Data
May 17, 2016 (KR) 10-2016-0060328

(51) Int. Cl. H01L 27/108; H01L 21/67; H01L 21/3215; H01L 21/02; H01L 21/311; H01L 21/285; H01L 49/02; H01L 21/324

(52) U.S. Cl. CPC H01L 27/10852; H01L 28/90; H01L 21/67103; H01L 21/324; H01L 21/02164; H01L 21/31116; H01L 21/28525; H01L 21/0217; H01L 21/3215

(57) ABSTRACT

A method of fabricating semiconductor device is provided. The method includes providing a substrate having a trench, plasma-ionizing a gas which comprises a deposition material precursor and a doping material precursor to respectively obtain a plasma-ionized deposition material and a plasma-ionized doping material, and depositing the plasma-ionized deposition material and the plasma-ionized doping material in the trench by applying a bias voltage to a bottom surface of the trench, wherein the bottom surface of the trench comprises a first material, and sidewalls of the trench comprise a second material different from the first material.

This application claims priority under 35 USC §119 to Korean Patent Application No. 10-2016-0060328 filed on May 17, 2016 in the Korean Intellectual Property Office, the disclosure of which is incorporated herein by reference in its entirety.

### BACKGROUND

### 1. Technical Field

The present disclosure relates to a method of fabricating a semiconductor device.

### 2. Description of the Related Art

In the rapidly developing electronics industry and information media, demands for a high speed, high reliability and a multi-functional ability has been increasing for semiconductor devices. In order to meet these demands, the structure of semiconductor devices has been getting more complex and the size of the semiconductor devices has been highly miniaturized.

Research is being conducted to increase the operation speed and integration density of semiconductor devices. A semiconductor device may include discrete devices such as a metal oxide semiconductor (MOS) transistor. As the semiconductor device becomes more highly integrated, a gate of the MOS transistor is becoming smaller, and a channel region under the gate is also becoming narrower.

In addition, as a gap between gates of transistors is reduced, a gap between a gate of a transistor and a contact formed on a source/drain region of the transistor is being reduced rapidly.

### SUMMARY

Aspects of the present inventive concept provide a method of fabricating a semiconductor device having a relatively narrow and deep contact structure, the method being employed to prevent a resistive defect in the contact structure.

Aspects of the present inventive concept also provide a method of fabricating a semiconductor device, the method being employed to highly dope a contact structure with a doping material.

However, aspects of the present inventive concept are not restricted to the one set forth herein. The above and other aspects of the present inventive concept will become more apparent to one of ordinary skill in the art to which the present inventive concept pertains by referencing the detailed description of the present inventive concept given below.

According to some embodiments of the present inventive concept, there is provided a method of fabricating a semiconductor device, the method comprising, providing a substrate having a trench, plasma-ionizing a gas which comprises a deposition material precursor and a doping material precursor to respectively obtain a plasma-ionized deposition material and a plasma-ionized doping material; and, depositing the plasma-ionized deposition material and the plasma-ionized doping material in the trench by applying a bias voltage to a bottom surface of the trench, wherein the bottom surface of the trench comprises a first material, and sidewalls of the trench comprise a second material different from the first material.

According to some embodiments of the present inventive concept, a method of fabricating a semiconductor device, the method comprising forming a trench in a substrate placed on a heater, providing a plasma-ionized deposition material precursor and a plasma-ionized doping material precursor into the trench to obtain a plasma-ionized deposition material and a plasma-ionized doping material, respectively, forming a contact structure by depositing the plasma-ionized deposition material and the plasma-ionized doping material in the trench by applying a bias voltage to a lower part of the substrate and forming a capacitor electrode on the contact structure.

According to some embodiments of the present inventive concept, a method of fabricating a semiconductor device, the method comprising providing a substrate having a trench; applying radio-frequency (RF) or microwave energy to a gas which comprises a deposition material precursor and a doping material precursor to respectively form a plasma-ionized deposition material and a plasma-ionized doping material; anisotropically depositing the plasma-ionized deposition material and the plasma-ionized doping material in the trench by applying a bias voltage to a bottom surface of the trench, wherein the bottom surface of the trench comprises a first material, and sidewalls of the trench comprise a second material different from the first material.

### BRIEF DESCRIPTION OF THE DRAWINGS

The above and other aspects and features of the present inventive concept will become more apparent by describing in detail exemplary embodiments thereof with reference to the attached drawings, in which:

FIG. 1 is an example cross-sectional view of a dynamic random access memory (DRAM) cell;

FIGS. 2A and 2B are diagrams illustrating a conventional trench-filling method;

FIG. 3 is an example circuit diagram of a DRAM cell;

FIG. 4 is an example cross-sectional view of a trench used to form an A region of FIG. 3;

FIG. 5 is an example cross-sectional view of a trench used to form a B region of FIG. 3;

FIGS. 6 through 8 are diagrams illustrating a method of fabricating a semiconductor device according to exemplary embodiments of the present inventive concept;

FIG. 9 is a scanning electron microscope (SEM) image obtained when a conventional deposition method is used;

FIG. 10 is an SEM image obtained when a method of fabricating a semiconductor device according to exemplary embodiments of the present inventive concept is used;

FIGS. 11 through 13 are diagrams illustrating a method of fabricating a semiconductor device according to exemplary embodiments of the present inventive concept;

FIG. 14 is an SEM image obtained when a conventional deposition method is used;

FIG. 15 is an SEM image obtained when a method of fabricating a semiconductor device according to exemplary embodiments of the present inventive concept is used; and

FIG. 16 is a block diagram of an electronic system including a semiconductor device formed using a method of fabricating a semiconductor device according to exemplary embodiments of the present inventive concept.

### DETAILED DESCRIPTION OF THE EMBODIMENTS

The present disclosure now will be described more fully hereinafter with reference to the accompanying drawings, in which various embodiments are shown. The invention may, however, be embodied in many different forms and should not be construed as limited to the example embodiments set forth herein. These example embodiments are just that—examples—and many implementations and variations are possible that do not require the details provided herein. It should also be emphasized that the disclosure provides details of alternative examples, but such listing of alternatives is not exhaustive. Furthermore, any consistency of detail between various examples should not be interpreted as requiring such detail—it is impracticable to list every possible variation for every feature described herein. The language of the claims should be referenced in determining the requirements of the invention.

In the drawings, like numbers refer to like elements throughout. Though the different figures show various features of exemplary embodiments, these figures and their features are not necessarily intended to be mutually exclusive from each other. Rather, certain features depicted and described in a particular figure may also be implemented with embodiment(s) depicted in different figure(s), even if such a combination is not separately illustrated. Referencing such features/figures with different embodiment labels (e.g. “first embodiment”) should not be interpreted as indicating certain features of one embodiment are mutually exclusive of and are not intended to be used with another embodiment.

Unless the context indicates otherwise, the terms first, second, third, etc., are used as labels to distinguish one element, component, region, layer or section from another element, component, region, layer or section (that may or may not be similar). Thus, a first element, component, region, layer or section discussed below in one section of the specification (or claim) may be referred to as a second element, component, region, layer or section in another section of the specification (or another claim).

Unless otherwise defined, all terms (including technical and scientific terms) used herein have the same meaning as commonly understood by one of ordinary skill consistent with their meaning in the context of the relevant art and/or the present application.

A method of fabricating a semiconductor device which will be described below relates to a method of fabricating a highly integrated silicon semiconductor device. However, the disclosure is not limited thereto. For example, the method of fabricating a semiconductor device according to the exemplary embodiments of the present inventive concept may be used to fabricate a semiconductor device in which a dynamic random access memory (DRAM) cell has a relatively narrow and deep contact structure. For example, the method of fabricating a semiconductor device according to the exemplary embodiments of the present inventive concept may be used when a trench for forming a contact structure is formed in a multilayer of different materials. To form a contact structure highly doped with a conductive material in this trench, the method of fabricating a semiconductor device according to the exemplary embodiments of the present inventive concept may be used.

Generally, if a trench is filled with a conductive material using a conventional thermal deposition method, a seam or a void may be created in a contact structure. The seam or void reduces the conductivity of the contact structure, thereby reducing the reliability of a semiconductor device. However, if the method of fabricating a semiconductor device according to the exemplary embodiments of the present inventive concept is used, the creation of a seam or a void in a contact structure may be reduced. Therefore, a contact structure having increased conductivity may be formed.

In a DRAM cell, the conductivity of a contact structure that electrically connects a capacitor electrode and a transistor under the capacitor electrode is important. Therefore, a DRAM cell with improved reliability may be fabricated using the method of fabricating a semiconductor device according to the exemplary embodiments of the present inventive concept.

The method of fabricating a semiconductor device according to the exemplary embodiments of the present inventive concept may be implemented by placing a wafer substrate on a support having a heater for heating the wafer substrate and using a silicon source gas that contains a silicon material, a doping gas that contains a doping material, and/or an etching gas for partially removing a deposition material in a trench. The above gases may form plasma-ionized materials through plasma discharge and form a highly doped contact structure without a seam or a void through a deposition process and/or an etching process with increased anisotropy which are/is performed at a low temperature (e.g., about 300⁰° C. to about 600⁰° C.).

When a highly doped silicon material is formed in a trench using conventional deposition method, it may be deposited unevenly in the trench due to the isotropy of the deposition of the silicon material. However, the anisotropy of the deposition of the silicon material may be increased using the method of fabricating a semiconductor device according to the exemplary embodiments of the present inventive concept. Therefore, the highly doped silicon material may be deposited in a bottom-up manner sequentially from a bottom surface of the trench, thereby forming a contact structure without a seam or a void.

The bottom-up manner denotes that a material is deposited from a bottom surface of a trench to the top of the trench and that the deposition of the material on sidewalls of the trench is minimized.

The structure of a DRAM cell that may be formed using the method of fabricating a semiconductor device according to the exemplary embodiments of the present inventive concept will be described herein.

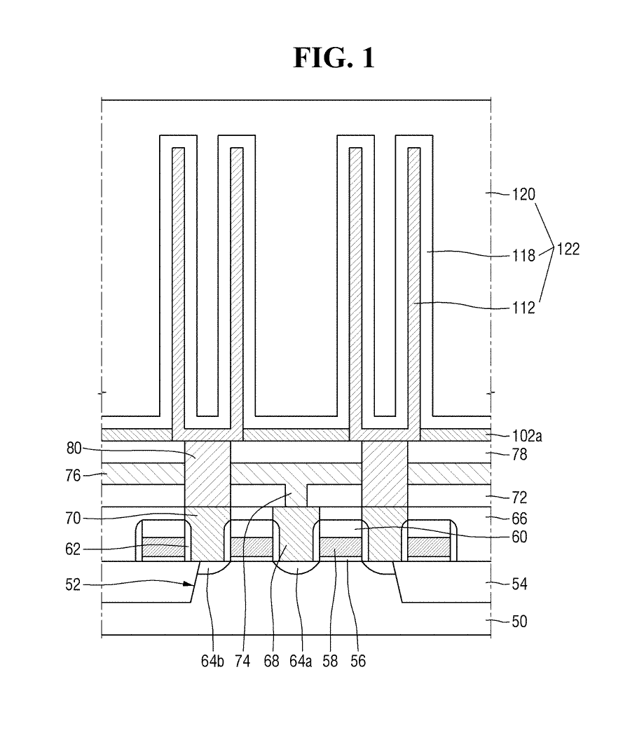

FIG. 1 is an example cross-sectional view of a DRAM cell.

Referring to FIG. 1, the DRAM cell may include a substrate 50, a device isolation layer pattern 54, a gate oxide layer 56, a gate electrode 58, a hard mask pattern 60, a spacer 62, a first interlayer insulating film 66, a first contact pad 68, a second contact pad 70, a second interlayer insulating film 72, a bit line contact 74, a bit line 76, a third interlayer insulating film 78, an etch stop layer pattern 102a, a bottom electrode 112, a dielectric layer 118, and a top electrode 120.

To form the DRAM cell, a pad oxide layer and a silicon nitride layer are formed sequentially on the substrate 50. The substrate 50 may be a semiconductor substrate such as a silicon substrate, a germanium substrate or a silicon-germanium substrate, a silicon-on-insulator (SOI) substrate, or a germanium-on-insulator (GOI) substrate.

A photoresist pattern is formed on the silicon nitride layer. The silicon nitride layer and the pad oxide layer are etched sequentially using the photoresist pattern as an etch mask, thereby forming a mask pattern including a pad oxide layer pattern and a silicon nitride layer pattern.

The substrate 50 is etched using the mask pattern as an etch mask, thereby forming a trench 52. A silicon oxide layer having superior gap-filling characteristics is formed in the trench 52 to fill the trench 52. The gap-filling characteristics may mean a characteristic that can fill the trench 52, without substantial formation of voids or seams in the trench 52. For example, the silicon oxide layer is polished by an etch-back process or a chemical-mechanical polishing (CMP) process, thereby forming the device isolation layer pattern 54 in the trench 52. The surface of the substrate 50 is divided into a field region and an active region by the device isolation layer pattern 54.

The gate oxide layer 56 is formed on the substrate 50, and a gate structure having the gate electrode 58 and the hard mask pattern 60 stacked is formed on the gate oxide layer 56.

In addition, the spacer 62 made of silicon nitride is formed on both sides of the gate structure. Impurities are ion-implanted using the gate structure and the spacer 62 as a mask. As a result, first and second impurity regions 64a and 64b which are to be provided as source/drain regions are formed in the substrate 50 on both sides of the gate structure.

The first interlayer insulating film 66 is formed to fully bury the gate structure, and the first contact pad 68 and the second contact pad 70 are formed to penetrate through the first interlayer insulating film 66 to be electrically connected to the first and second impurity regions 64a and 64b, respectively. The first contact pad 68 and the second contact pad 70 may be, for example, conductive pads formed of a conductive material such as a metal for establishing an electrical connection between a bit line (e.g., bit line 76) and a drain (e.g., impurity regions 64a/64b), and an electrical connection between a capacitor (e.g., capacitor 122) and a source (e.g., impurity regions 64a/64b).

The method of fabricating a semiconductor according to the exemplary embodiments of the present inventive concept may be used to form the first contact pad 68 and the second contact pad 70. This will be described in detail later.

The second interlayer insulating film 72 is formed on the first interlayer insulating film 66. The bit line contact 74 is formed to penetrate through the second interlayer insulating film 72 and thus contact the first contact pad 68. The bit line contact 74 is electrically connected to the first impurity region 64a by the first contact pad 68. In addition, the bit line 76 is formed on the second interlayer insulating film 72 to be electrically connected to the bit line contact 74.

Next, the third interlayer insulating film 78 is formed on the second interlayer insulating film 72 to cover the bit line 76. The third interlayer insulating film 78 may be formed by depositing silicon oxide using a chemical vapor deposition (CVD) method.

The third interlayer insulating film 78 and the second interlayer insulating film 72 are partially etched to form contact holes which expose an upper surface of the second contact pad 70. A storage node contact 80 is formed by filling each of the contact holes with a conductive material and polishing the conductive material. The storage node contact 80 is electrically connected to the second impurity region 64b by the second contact pad 70.

When the storage node contact 80 is formed by filling each of the contact holes with the conductive material, the method of fabricating a semiconductor device according to the exemplary embodiments of the present inventive concept may be used. This will be described in detail later.

Through the above-described process, wiring layers connected to impurity regions of a select transistor of the DRAM cell are formed.

The etch stop layer pattern 102a is formed on the third interlayer insulating film 78. In addition, a capacitor 122 electrically connected to the storage node contact 80 is formed.

The capacitor 122 includes the bottom electrode 112, the dielectric layer 118, and the top electrode 120.

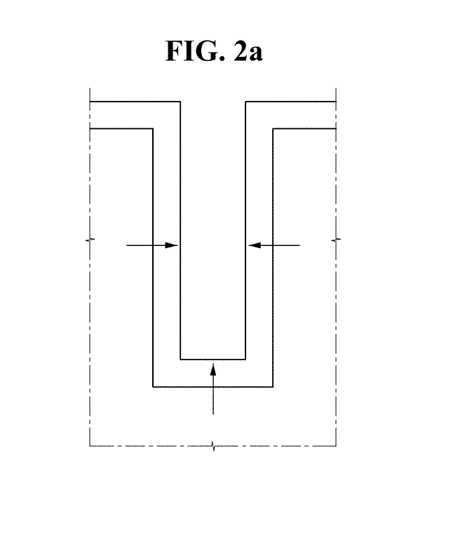

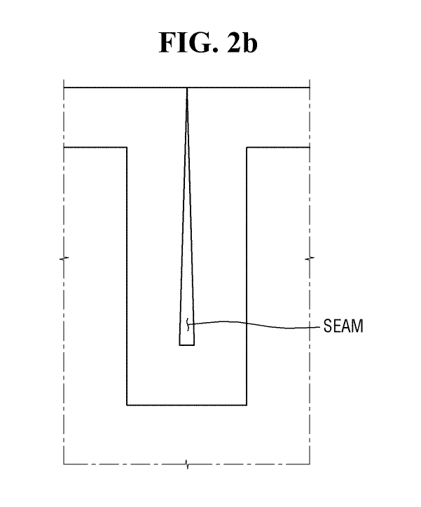

FIGS. 2A and 2B are diagrams illustrating a conventional trench-filling method.

When a trench is filled with a conductive material using a thermal deposition method, a seam structure may be created in the trench due to isotropic deposition characteristics. For example, with the trend toward shrinkage of semiconductor devices, a highly doped contact structure is required as trenches become relatively narrower and deeper.

If an isotropic deposition method is used to form a highly doped contact structure, the probability that a seam structure will be created in the contact structure increases because the etch or deposition rate is uniform in all directions in an isotropic deposition method compared to an anisotropic deposition method in which the etch or deposition rate is generally unidirectional depending on the growth direction. In addition, even if seam structures of similar sizes are created in the contact structure, they may cause a resistive defect if the contact structure is relatively narrow and deep, thereby significantly reducing the reliability of a semiconductor device.

The method of fabricating a semiconductor device according to the exemplary embodiments of the present inventive concept is designed to prevent the creation of a seam or a void in a contact structure through anisotropic deposition in a bottom-up manner, instead of the conventional isotropic deposition method.

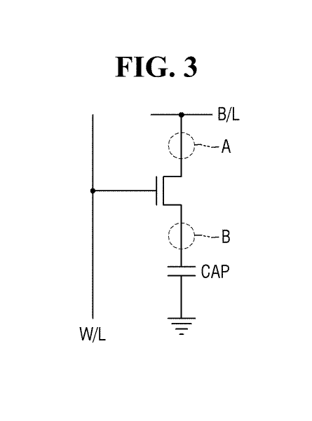

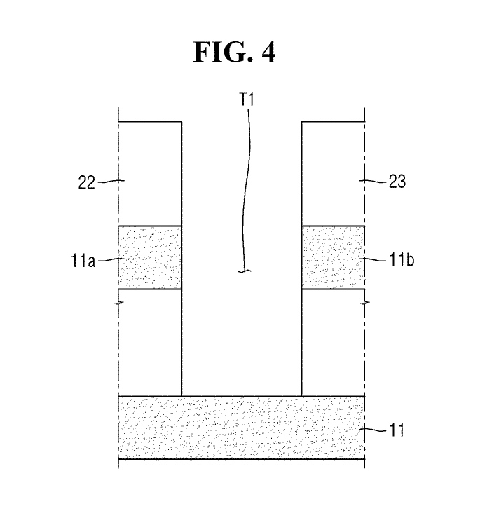

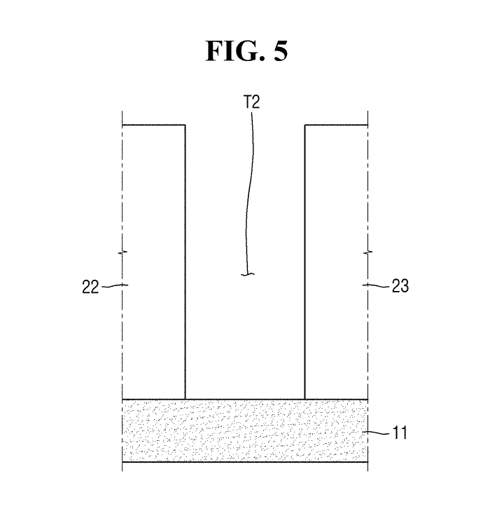

FIG. 3 is an example circuit diagram of a DRAM cell. FIG. 4 is an example cross-sectional view of a trench T1 used to form an A region of FIG. 3. FIG. 5 is an example cross-sectional view of a trench T2 used to form a B region of FIG. 3.

Referring to FIG. 3, a contact structure of the DRAM cell includes a first contact structure (the A region) which connects a transistor and a bit line (e.g., a bit line as shown in FIG. 1) and a second contact structure (the B region) which connects the transistor and a capacitor (e.g., a capacitor 122 as shown in FIG. 1).

Referring to FIG. 4, a first material layer 11 may be formed on a bottom surface of the trench T1, and a second material layer 22 and 23 may be formed on sidewalls of the trench T1. A first material layer 11a and 11b may be formed between portions of the second material layer 22 and 23. For example, the trench T1 may be formed in a multilayer of different materials.

Referring to FIG. 5, a first material layer 11 may be formed on a bottom surface of the trench T2, and a second material layer 22 and 23 may be formed on sidewalls of the trench T2. For example, the trench T2 may be formed in a multilayer of different materials.

If a deposition material is deposited in each of the trenches T1 and T2 of FIGS. 4 and 5 using a thermal deposition method, a seam or void structure may be created in the trenches T1 and T2 due to isotropic deposition characteristics.

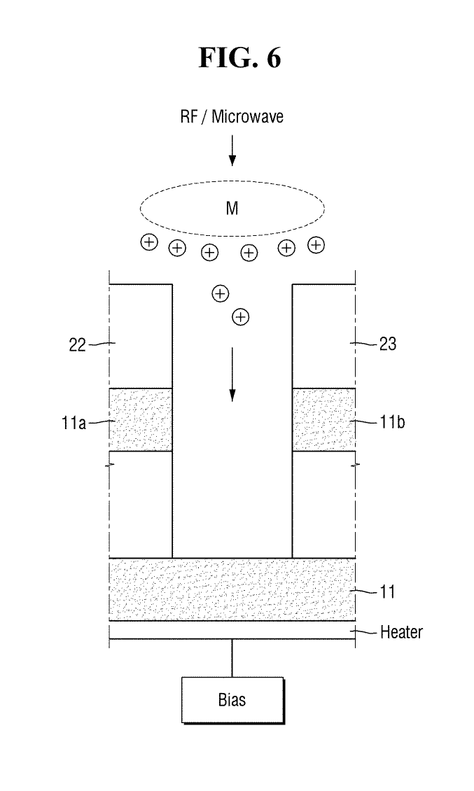

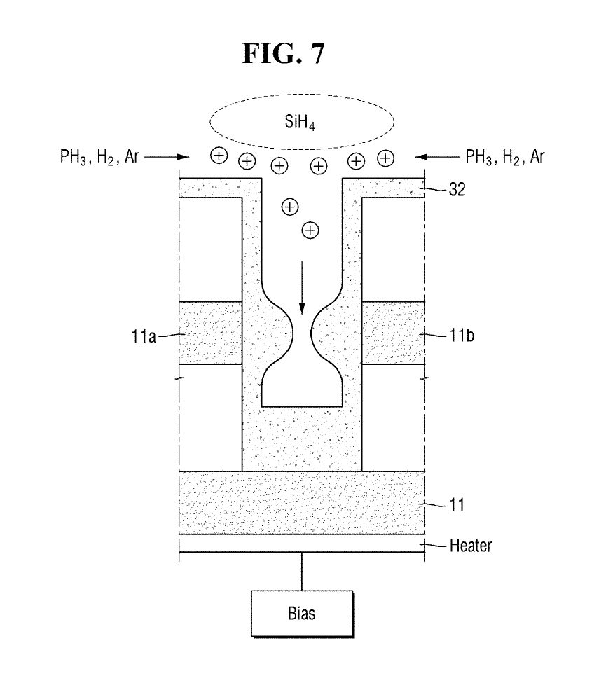

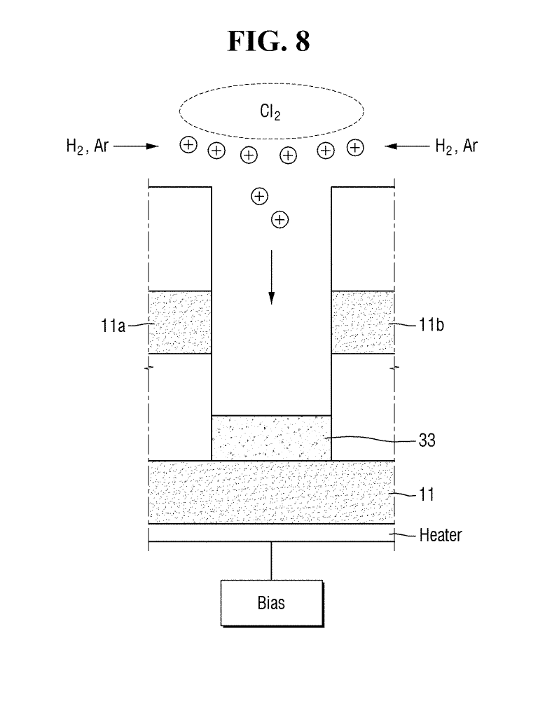

FIGS. 6 through 8 are diagrams illustrating a method of fabricating a semiconductor device according to exemplary embodiments of the present inventive concept.

Referring to FIGS. 6 through 8, a heater may be placed under a first material layer 11. In FIGS. 6 through 8, the heater is placed under the first material layer 11 to directly contact the first material layer 11. However, the disclosure is not limited thereto. In some embodiments, another element may be placed between the first material layer 11 and the heater.

The heater provides a predetermined processing temperature so that a trench T1 may be highly doped with a doping material when a deposition material is deposited in the trench T1. For example, the heater may maintain the processing temperature at about 300⁰° C. to about 600⁰° C. so that the trench T1 may be highly doped with the doping material.

A processing gas M may be provided to a substrate having the trench T1. The processing gas M may include a deposition material and a doping material. Radio frequency (RF) waves and/or microwaves may be provided to the processing gas M so that sufficient energy may be provided to the deposition material and the doping material to change their gaseous state to a plasma state thereby plasma-ionizing the deposition material and the doping material included in the processing gas M. For example, the plasma-ionized deposition material may be a hot ionized gas of the deposition material consisting of approximately equal numbers of free positively charged ions (+) and free negatively charged electrons (−) of the deposition material and the plasma-ionized doping material may be a hot ionized gas of the doping material consisting of approximately equal numbers of free positively charged ions (+) and free negatively charged electrons (−) of the doping material.

A bias voltage may be applied to a lower part of the substrate having the trench T1. Accordingly, the plasma-ionized deposition material and the plasma-ionized doping material may be deposited in the trench T1 in a bottom-up manner. The method of fabricating a semiconductor device according to the exemplary embodiments of the present inventive concept comprises deposition of the highly doped silicon material in a bottom-up manner sequentially from a bottom surface of the trench. The bottom-up manner denotes that a material is deposited from a bottom surface of a trench to the top of the trench and that the deposition of the material on sidewalls of the trench is minimized. The bottom-up manner according to the present inventive concept may comprise deposition process for depositing the plasma-ionized deposition material and the plasma-ionized doping material in the trench T1 and etching process for removing the material deposited on the sidewalls of the trench T1.

In particular, the first material layer 11, 11a and 11b may include silicon (Si), and a second material layer 22 and 23 may include silicon oxide (SiO₂) and/or silicon nitride (SiN).

The processing gas M may include at least one of SiH₄, SiH₂Cl₂ and Si₂H₆ as the precursor of the deposition material and any one of PH₃ and B₂H₆ as the precursor of the doping material. The deposition material may be silicon (Si) or another semiconductor material. The doping material may comprise one or more atomic elements (e.g., phosphorus P or boron B) that act as a charge carrier (e.g., electrons or holes) when doped within a semiconductor material. The RF waves and/or the microwaves provided to the processing gas M may plasma-ionize the deposition material and the doping material, and the plasma-ionized deposition material and the plasma-ionized doping material may be deposited in the trench T1 by an anisotropic deposition method.

When at least one of SiH₄, SiH₂Cl₂ and Si₂H₆ is used as the precursor of the deposition material, the plasma-ionized deposition material may comprise plasma-ionized silicon (Si). Since the plasma-ionized deposition material is the same material as the first material layer 11, 11a and 11b, it may be deposited and grown in the trench T1. For example, the plasma-ionized deposition material may be deposited and grown in the trench T1 with anisotropic deposition characteristics by applying a bias voltage to a lower part of the trench T1.

In addition, when a contact structure is formed by depositing the deposition material in the trench T1, the doping material may also be provided in order to improve the conductivity of the contact structure. Since the precursor of the doping material such as PH₃ or B₂H₆ is also plasma-ionized and provided accordingly, the doping material may be doped with the plasma-ionized deposition material with anisotropic deposition characteristics in the trench T1.

In the method of fabricating a semiconductor device according to the exemplary embodiments of the present inventive concept, a deposition process is performed in the trench T1 in a bottom-up manner using plasma-ionized materials and a bias voltage. Therefore, the deposition process may be performed in a relatively low processing temperature environment (e.g., about 300⁰° C. to about 600⁰° C.), and a contact structure highly doped with the doping material may be formed.

In the method of fabricating a semiconductor device according to the exemplary embodiments of the present inventive concept, an etching gas may also be provided in the deposition process in order to deposit the deposition material in the bottom-up manner. While the deposition material is deposited in the trench T1 from a bottom surface of the trench T1, some of the deposition material may also be deposited on sidewalls of the trench T1. Therefore, the material deposited on the sidewalls of the trench T1 needs to be removed.

The material deposited on the sidewalls of the trench T1 is relatively smaller in amount than the material deposited on the bottom surface of the trench T1 because the plasma-ionized deposition material is deposited and grown in the trench T1 by a deposition process having anisotropic characteristics in which the deposition rate is generally unidirectional, e.g., downward direction as illustrated in the exemplary embodiment of FIG. 6. However, the material deposited on the sidewalls of the trench T1 needs to be removed in order to realize the bottom-up manner.

For example, at least one of Cl₂, HCl, and H₂ may be used as a precursor of the etching material. The precursor of the etching material may be provided and plasma-ionized together with the deposition material and the doping material by the same plasma ionizing process disclosed above. In addition, an etching process for removing materials deposited on the sidewalls of the trench T1 may be performed at the same time (e.g., simultaneously) as the process of depositing the deposition material in the trench T1. In some embodiments, an isotropic etching process for removing materials deposited on the sidewalls of the trench T1 may be performed by using the plasma-ionized etching material.

In the method of fabricating a semiconductor device according to the exemplary embodiments of the present inventive concept, after the deposition of the deposition material and the doping material in the trench T1, an etching process may be performed as a separate process by providing the etching material to the trench T1. The deposition process and the etching process may be repeatedly performed, thereby forming a contact structure highly doped with the doping material in the trench T1.

For example, a technical feature of the method of fabricating a semiconductor device according to the exemplary embodiments of the present inventive concept is to realize the bottom-up manner in the formation of a contact structure highly doped with the doping material in the trench T1. To this end, a deposition process is performed by applying a bias voltage to plasma-ionized materials. In addition, an etching process for removing materials deposited on the sidewalls of the trench Ti is performed at the same time as the deposition process or separately from the deposition process.

A relatively low processing temperature (e.g., about 300⁰° C. to about 600⁰° C.) needs to be maintained in order to highly dope the contact structure with the doping material, and the plasma-ionized deposition material and the plasma-ionized doping material are deposited in the trench T1 in the bottom-up manner by applying a bias voltage to the plasma-ionized deposition material and the plasma-ionized doping material.

The method of fabricating a semiconductor device according to the exemplary embodiments of the present inventive concept may be used under a relatively low processing pressure of, e.g., about 10 mTorr to about 200 mTorr. This is a relatively lower pressure than the pressure under which the conventional thermal deposition method is used.

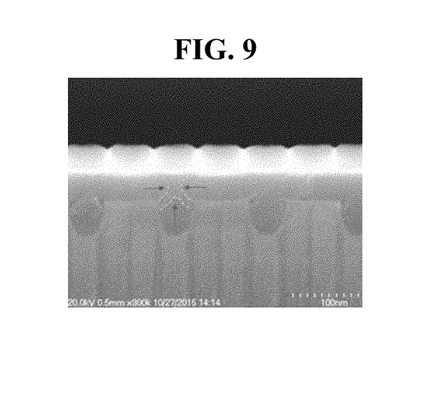

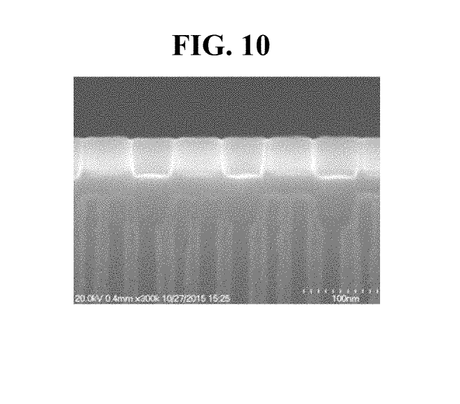

FIG. 9 is a scanning electron microscope (SEM) image obtained when a conventional deposition method is used. FIG. 10 is an SEM image obtained when a method of fabricating a semiconductor device according to the exemplary embodiments of the present inventive concept is used.

Referring to FIGS. 9 and 10, when the conventional deposition method is used, a resistive defect may be created in a contact stricture. When the method of fabricating a semiconductor device according to the exemplary embodiments of the present inventive concept is used, the resistive defect problem may be improved.

As the layer configuration on sidewalls of a trench T1 becomes complicated, anisotropic deposition characteristics need to be increased, which may be accomplished by depositing a plasma-ionized deposition material and a plasma-ionized doping material in the trench T1 by applying a bias voltage to the plasma-ionized deposition material and the plasma-ionized doping material.

FIG. 9 shows a resistive defect resulting from the deposition of a deposition material in a first material layer 11, 11a and 11b when no bias voltage is applied. FIG. 10 shows the result of increasing the anisotropic deposition characteristics by applying a bias voltage according to the exemplary embodiments of the present inventive concept.

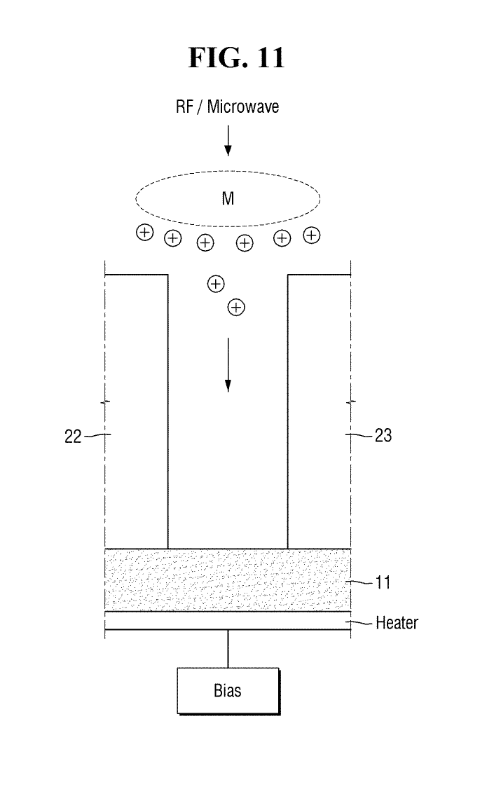

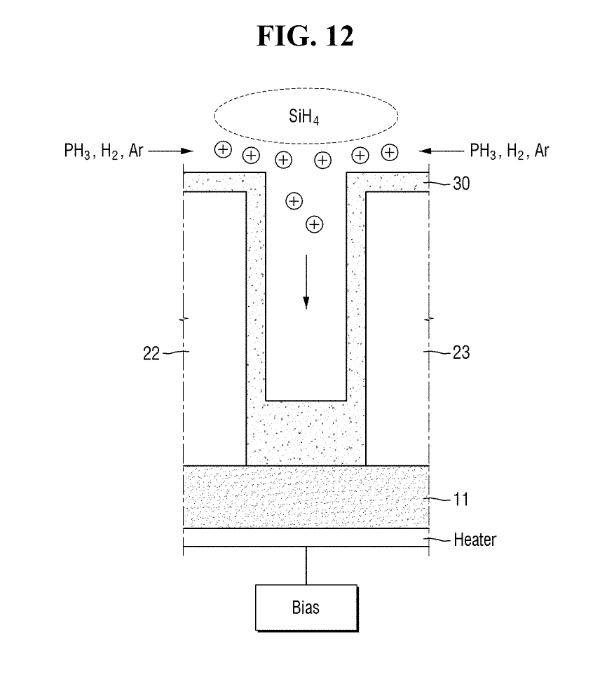

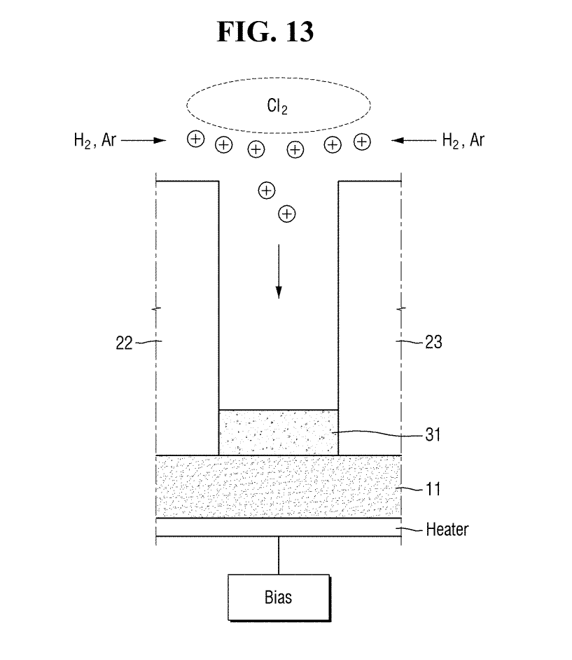

FIGS. 11 through 13 are diagrams illustrating a method of fabricating a semiconductor device according to exemplary embodiments of the present inventive concept.

Referring to FIGS. 11 through 13, a heater may be placed under a first material layer 11. In FIGS. 11 through 13, the heater is placed under the first material layer 11 to directly contact the first material layer 11. However, the disclosure is not limited thereto. In some embodiments, another element may be placed between the first material layer 11 and the heater.

The heater provides a predetermined processing temperature so that a trench T2 may be highly doped with a doping material when a deposition material is deposited in the trench T2. For example, the heater may maintain the processing temperature at about 300⁰° C. to about 600⁰° C. so that the trench T2 may be highly doped with the doping material.

A processing gas M may be provided to a substrate having the trench T2. The processing gas M may contain a deposition material and a doping material. RF waves and/or microwaves may be provided to the processing gas M, thereby plasma-ionizing the deposition material and the doping material existing in the processing gas M by the same plasma ionizing process disclosed above with respect to FIGS. 6-8.

A bias voltage may be applied to a lower part of the substrate having the trench T2. Accordingly, the plasma-ionized deposition material and the plasma-ionized doping material may be deposited in the trench T2 in a bottom-up manner.

For example, the first material layer 11 may include silicon (Si), and a second material layer 22 and 23 may include silicon oxide (SiO₂) and/or silicon nitride (SiN).

The processing gas M may include at least one of SiH₄, SiH₂Cl₂ and Si₂H₆ as the precursor of the deposition material and any one of PH₃ and B₂H₆ as the precursor of the doping material. The deposition material may be silicon (Si) or another semiconductor material. The doping material may comprise one or more atomic elements (e.g., phosphorus P or boron B) that act as a charge carrier (e.g., electrons or holes) when doped within a semiconductor material. The RF waves and/or the microwaves provided to the processing gas M may plasma-ionize the deposition material and the doping material, and the plasma-ionized deposition material and the plasma-ionized doping material may be deposited in the trench T2 by an anisotropic deposition method disclosed above with respect to FIGS. 6-8.

When at least one of SiH₄, SiH₂Cl₂ and Si₂H₆ is used as the precursor of the deposition material, the plasma-ionized deposition material may contain plasma-ionized silicon (Si). Since the plasma-ionized deposition material is the same material as the first material layer 11, it may be deposited and grown in the trench T2. For example, the plasma-ionized deposition material may be deposited and grown in the trench T2 with anisotropic deposition characteristics by applying a bias voltage to a lower part of the trench T2.

In addition, when a contact structure is formed by depositing the deposition material in the trench T2, the doping material may also be provided in order to improve the conductivity of the contact structure. Since the precursor of the doping material such as PH₃ or B₂H₆ is also plasma-ionized and provided accordingly, the doping material may be doped with the plasma-ionized deposition material with anisotropic deposition characteristics in the trench T2.

In the method of fabricating a semiconductor device according to the exemplary embodiments of the present inventive concept, a deposition process is performed in the trench T2 in a bottom-up manner using plasma-ionized materials and a bias voltage. Therefore, the deposition process may be performed in a relatively low processing temperature environment (e.g., about 300⁰° C. to about 600⁰° C.), and a contact structure highly doped with the doping material may be formed.

In the method of fabricating a semiconductor device according to the exemplary embodiments of the present inventive concept, an etching gas may also be provided in the deposition process in order to deposit the deposition material in the bottom-up manner. While the deposition material is deposited in the trench T2 from a bottom surface of the trench T2, some of the deposition material may also be deposited on sidewalls of the trench T2. Therefore, the material deposited on the sidewalls of the trench T2 needs to be removed.

The material deposited on the sidewalls of the trench T2 is relatively smaller in amount than the material deposited on the bottom surface of the trench T2 because the plasma-ionized deposition material is deposited and grown in the trench T2 by an anisotropic deposition process in which the deposition rate is generally unidirectional, e.g., downward direction as illustrated in the exemplary embodiment of FIG. 11. However, the material deposited on the sidewalls of the trench T2 needs to be removed in order to realize the bottom-up manner.

For example, at least one of Cl₂, HCl, and H₂ may be used as a precursor of the etching material. The precursor of the etching material may be provided and plasma-ionized together with the deposition material and the doping material. In addition, an etching process for removing materials deposited on the sidewalls of the trench T2 may be performed at the same time (e.g., simultaneously) as the process of depositing the deposition material in the trench T2. In some embodiments, an isotropic etching process for removing materials deposited on the sidewalls of the trench T2 may be performed by using the plasma-ionized etching material.

In the method of fabricating a semiconductor device according to the exemplary embodiments of the present inventive concept, after the deposition of the deposition material and the doping material in the trench T2, an etching process may be performed as a separate process by providing the etching material to the trench T2. The deposition process and the etching process may be repeatedly performed, thereby forming a contact structure highly doped with the doping material in the trench T2.

The method of fabricating a semiconductor device according to the exemplary embodiments of the present inventive concept may be used under a relatively low processing pressure of, e.g., about 10 mTorr to about 200 mTorr. This is a relatively lower pressure than the pressure under which the conventional thermal deposition method is used.

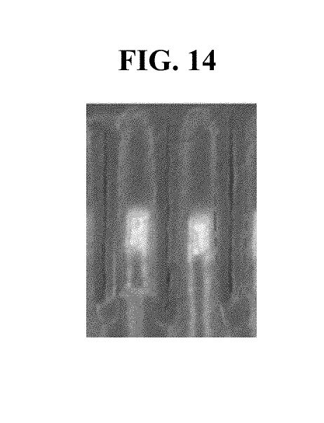

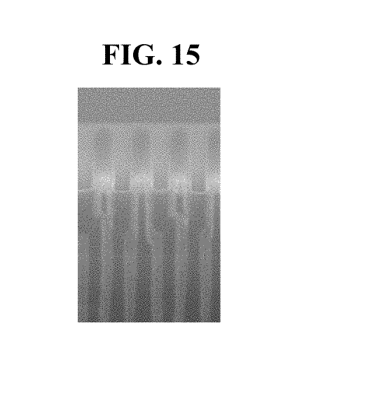

FIG. 14 is an SEM image obtained when a conventional deposition method is used. FIG. 15 is an SEM image obtained when a method of fabricating a semiconductor device according to the exemplary embodiments of the present inventive concept is used.

Referring to FIGS. 14 and 15, when the conventional deposition method is used, a resistive defect such as a seam may be created in a contact stricture. When the method of fabricating a semiconductor device according to the exemplary embodiments of the present inventive concept is used, the resistive defect problem may be improved.

FIG. 14 shows a resistive defect (such as a seam) resulting from the deposition of a deposition material in the trench T2 using a conventional thermal deposition method. FIG. 15 shows the result of depositing the deposition material in the trench T2 in a bottom-up manner according to the exemplary embodiments of the present inventive concept.

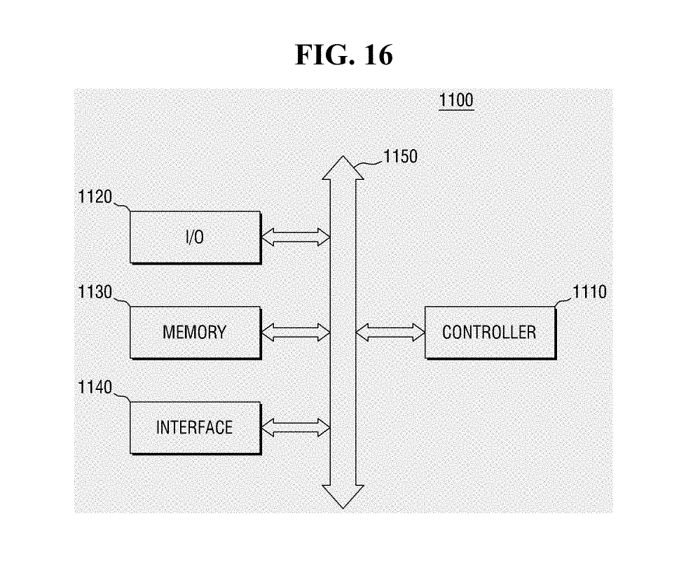

FIG. 16 is a block diagram of an electronic system 1100 including a semiconductor device formed using a method of fabricating a semiconductor device according to exemplary embodiments of the present inventive concept.

As used herein, a semiconductor device may refer to a device such as a semiconductor chip (e.g., memory chip and/or logic chip formed on a die), a stack of semiconductor chips, a semiconductor package including one or more semiconductor chips stacked on a package substrate, or a package-on-package device including a plurality of packages. These devices may be formed using ball grid arrays, wire bonding, through substrate vias, or other electrical connection elements, and may include memory devices such as volatile or non-volatile memory devices.

Referring to FIG. 16, the electronic system 1100 may include a controller 1110, an input/output (I/O) device 1120, a memory device 1130, an interface 1140 and a bus 1150.

The controller 1110, the I/O device 1120, the memory device 1130 and/or the interface 1140 may be connected to one another by the bus 1150. The bus 1150 may serve as a path for transmitting data.

The controller 1110 may include at least one of a microprocessor, a digital signal processor, a microcontroller and logic devices capable of performing similar functions to those of a microprocessor, a digital signal processor and a microcontroller.

The I/O device 1120 may include a keypad, a keyboard, a display device, etc.

The memory device 1130 may store data and/or commands. The electronic system 1100 may include a high-speed DRAM or static random access memory (SRAM) as the memory device 1130 for improving the operation of the controller 1110.

The interface 1140 may be used to transmit data to or receive data from a communication network. The interface 1140 may be a wired or wireless interface. In an example, the interface 1140 may include an antenna or a wired or wireless transceiver.

A semiconductor device fabricated according to embodiments of the present inventive concept may be provided in the memory device 1130.

The electronic system 1100 may be applied to nearly all types of electronic products capable of transmitting and/or receiving information in a wireless environment, such as a personal data assistant (PDA), a portable computer, a web tablet, a wireless phone, a mobile phone, a digital music player, a memory card, etc.

While the present inventive concept has been particularly shown and described with reference to exemplary embodiments thereof, it will be understood by those of ordinary skill in the art that various changes in form and details may be made therein without departing from the spirit and scope of the present inventive concept as defined by the following claims. It is therefore desired that the present embodiments be considered in all respects as illustrative and not restrictive, reference being made to the appended claims rather than the foregoing description to indicate the scope of the invention.

What is claimed is:

1. A method of fabricating a semiconductor device, the method comprising:
providing a substrate having a trench;
plasma-ionizing a gas which comprises a deposition material precursor and a doping material precursor to respectively obtain a plasma-ionized deposition material and a plasma-ionized doping material;
depositing the plasma-ionized deposition material and the plasma-ionized doping material in the trench by applying a bias voltage to a bottom surface of the trench; and
removing a material deposited on the sidewalls of the trench,
wherein the bottom surface of the trench comprises a first material, and sidewalls of the trench comprise a second material different from the first material.

2. The method of claim 1, wherein the deposition material comprises the same material as the first material.

3. The method of claim 2, wherein the gas further comprises an etching material.

4. The method of claim 3, wherein the etching material comprises at least one of Cl₂, HCl, and H₂.

5. The method of claim 1, wherein the removing a material deposited on the sidewalls of the trench is performed using a plasma-ionized etching material and is performed after the deposition of the plasma-ionized deposition material and the plasma-ionized doping material in the trench.

6. The method of claim 1, further comprising providing heat to the substrate by placing a heater under the substrate.

7. The method of claim 1, wherein the first material comprises Si, and the second material comprises at least one of SiO₂ and SiN.

8. A method of fabricating a semiconductor device, the method comprising:
forming a trench in a substrate placed on a heater;
providing a plasma-ionized deposition material precursor and a plasma-ionized doping material precursor into the trench to obtain a plasma-ionized deposition material and a plasma-ionized doping material, respectively;
forming a contact structure by depositing the plasma-ionized deposition material and the plasma-ionized doping material in the trench by applying a bias voltage to a lower part of the substrate and removing a material deposited on the sidewalls of the trench; and
forming a capacitor electrode on the contact structure.

9. The method of claim 8, further comprising providing a plasma-ionized etching material into the trench, wherein the plasma-ionized etching material removes a material deposited on sidewalls of the trench.

10. The method of claim 9, wherein the plasma-ionized deposition material, the plasma-ionized doping material, and the plasma-ionized etching material are provided simultaneously into the trench.

11. The method of claim 10, wherein the deposition material precursor comprises at least one of SiH₄, SiH₂Cl₂, and Si₂H₆.

12. The method of claim 10, wherein the doping material precursor comprises any one of PH₃ and B₂H₆.

13. The method of claim 10, wherein the etching material precursor comprises at least one of Cl₂, HCl, and H₂.

14. A method of fabricating a semiconductor device, the method comprising:
providing a substrate having a trench;
applying radio-frequency (RF) or microwave energy to a gas which comprises a deposition material precursor and a doping material precursor to respectively form a plasma-ionized deposition material and a plasma-ionized doping material;
anisotropically depositing the plasma-ionized deposition material and the plasma-ionized doping material in the trench by applying a bias voltage to a bottom surface of the trench,
wherein the bottom surface of the trench comprises a first material, and sidewalls of the trench comprise a second material different from the first material.

15. The method of claim 14, wherein the gas further comprises etching material precursor, and the step of applying further comprises applying radio-frequency (RF) or microwave energy to the gas to form a plasma-ionized etching material.

16. The method of claim 15, further comprising isotropically providing the plasma-ionized etching material into the trench, wherein the plasma-ionized etching material removes at least a portion of the deposited plasma-ionized deposition material that has been deposited on sidewalls of the trench.

17. The method of claim 15, wherein the plasma-ionized deposition material, the plasma-ionized doping material, and the plasma-ionized etching material are provided simultaneously into the trench.

18. The method of claim 15, wherein the etching material precursor comprises at least one of Cl₂, HCl, and H₂, the deposition material precursor comprises at least one of SiH₄, SiH₂Cl₂, and Si₂H₆, and the doping material precursor comprises any one of PH₃ and B₂H₆.

19. The method of claim 14, further comprising providing heat to the substrate by placing a heater under the substrate.

20. The method of claim 14, wherein the first material comprises Si, and the second material comprises at least one of SiO₂ and SiN.
